(19) United States
(12) Patent Application Publication
(10) Pub. No.: US 2006/0157748 A1
(43) Pub. Date: Jul. 20, 2006

(54) Metal junction diode and process

(76) Inventors: Nui Chong, San Jose, CA (US); Farrokh Omid-Zohoor, Sunnyvale, CA (US)

Correspondence Address: LATTICE SEMICONDUCTOR CORPORATION, 5555 NE MOORE COURT, HILLSBORO, OR, 97124-6421, US

(21) Appl. No.: 11/038,998

(22) Filed: Jan. 20, 2005

(51) Int. Cl. H01L 29/76

(52) U.S. Cl. 257/288

(57) ABSTRACT

A junction diode includes a substrate having first and second cathode regions separated by an anode region. Metal silicide layers contact the first and second cathode regions and the anode regions. The anode region has a doping concentration sufficient to create a depletion region in the anode region adjacent to the metal silicide layer contacting the anode region. A fabrication process includes forming the anode region to have a doping concentration that increases in a direction into the anode region away from the substrate surface.

### TECHNICAL FIELD

The present invention relates, generally, to semiconductor devices and to processes for their fabrication and, more particularly, to semiconductor devices including diodes and to processes for their fabrication.

### BACKGROUND

Diodes have found wide ranging application in integrated circuit technology. For example, as integrated circuits increase in complexity and decrease in size, the circuits become more susceptible to damage from high voltage transients. Circuits having such small feature sizes are vulnerable to dielectric breakdown during high voltage transients. Additionally, many circuits such as memory devices and the like include high speed input/output nodes that require individual high-voltage protection devices. Accordingly, many circuits require multiple high-voltage protection devices, such as input protection diodes.

Various diode configurations have been developed for integration into standard circuit fabrication processes. Semiconductor metal junction diodes are typically formed by creating p+ and n+ regions in a semiconductor substrate. This particular diode structure is highly compatible with processes used to form complimentary-metal-oxide-semiconductor (CMOS) devices. The p-n junction can be created by special ion implantation processes devoted to the creation of the n+ and p+ regions in the substrate, or by taking advantage of the p-n junctions created in the substrate by the p+ and n+ well regions.

Further improvement diode performance can be realized by creating diodes with depleted polysilicon gate structures. These diodes are known as polysilicon gate diodes, or poly-bounded diodes. In the poly-bounded diode, a silicon channel region beneath the polysilicon layer separates the n+ region and the p+ region in the substrate. The silicon channel region improves diode performance by dissipating heat and reducing the current density through the diode. Such diodes are particularly effective in protecting circuits from high-voltage transients and can be fabricated to have low parasitic capacitance.

Diodes fabricated by forming a metal-semiconductor contact have many advantages over semiconductor p-n metal junction diodes. For example, metal junction diodes, also known as Schottky diodes, have lower forward voltage drop, relatively lower capacitance, and faster reverse recovery times in comparison with semiconductor p-n metal junction diodes. These characteristics make metal junction diodes particularly advantages for use in high-speed integrated circuits. The metal junction diodes, however, are often incompatible with standard CMOS device fabrication.

While poly-bounded diodes offer an effective means for protecting integrated circuits against high-voltage transients, and metal junction diodes offer advantages for use in high-speed semiconductor devices, further improvements in diode design and fabrication techniques are needed to enable the integration of high-speed diode technology in integrated circuits and other components that having CMOS devices.

### SUMMARY

In accordance with one embodiment of the invention, a metal junction diode includes a substrate having a substrate surface and having a lightly-doped region extending into the substrate from the substrate surface. First and second cathode regions reside in the lightly-doped region and extend into the substrate from the substrate surface. An anode region separates the first and second cathode regions. Metal silicide layers contact the first and second cathode regions and the anode regions at the substrate surface.

In another embodiment of the invention, a metal junction diode includes a substrate having first and second cathode regions separated by an anode region. Cobalt silicide layers contact the first and second cathode regions and the anode region. The anode region has a doping concentration sufficient to create a depletion region in the anode region adjacent to the cobalt silicide layer that contacts the anode regions.

In yet another embodiment of the invention, a process for fabricating a metal junction diode includes providing a silicon substrate of a first conductivity type and having a substrate surface. An anode region of a second conductivity type is formed in the semiconductor substrate. The anode region has a doping concentration that increases in the direction away from the substrate surface. Cathode regions of the second conductivity type are formed in the semiconductor substrate. Metal silicide contacts are formed to the anode region and to the cathode regions.

### BRIEF DESCRIPTION OF THE DRAWING

FIG. 1 is a cross-sectional view of a metal junction diode configured in accordance with one embodiment of the invention;

FIG. 2 is a cross-sectional view of the metal junction diode illustrated in FIG. 1 having additional dope regions therein;

FIG. 3 is a cross-sectional view of a metal junction diode fabricated in accordance with another embodiment of the invention;

FIG. 4 is a cross-sectional view of the metal junction diode illustrated in FIG. 3 with additional dope regions therein;

FIG. 5 is a cross-sectional view of a metal junction diode configured in accordance with yet another embodiment of the invention;

FIG. 6 is a cross-sectional view of the metal junction diode illustrated in FIG. 5 having additional dope regions therein; and

FIG. 7 is a plot of current versus voltage for two metal junction diodes fabricated in accordance with the invention.

It would be appreciated that for simplicity and clarity of illustration, elements shown in the Figures have not necessarily been drawn to scale. For example, the dimensions of some of the elements are exaggerated relative to each other for clarity. Further, where considered appropriate, reference numerals have been repeated among the Figures to indicate corresponding elements.

### DETAILED DESCRIPTION

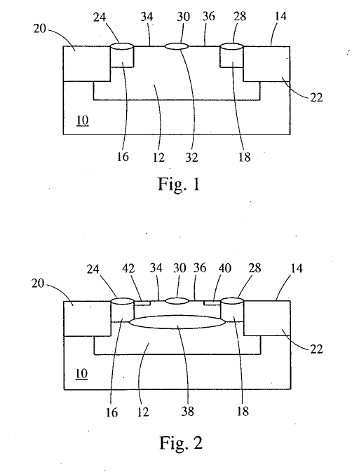

Shown in FIG. 1, in cross-section, is a semiconductor substrate 10 having an anode region 12 formed therein. Anode region 12 extends into semiconductor substrate 10 from a substrate surface 14. In the illustrated embodiment, anode region 12 is a region of semiconductor substrate 10 having an n-type conductivity, while semiconductor substrate 10 has a p-type conductivity. Although the illustrated embodiments will be described with reference to a particular doping conductivity relationship, the invention is not limited to the particular relationship. Further, semiconductor substrate 10 can be any of a number of different substrate materials, such as an epitaxial silicon material, a silicon-on-insulator (SOI) material, and the like.

In the illustrated embodiment, anode region 12 is an n-well region formed in semiconductor substrate 10 by ion implantation of an n-type dopant, such as phosphorous or arsenic, or the like. In one embodiment of the invention, anode region 12 is doped to have a retrograde doping profile. The retrograde profile provides an n-well region having a relatively low doping concentration in regions approximate to substrate surface 14, while having a relatively higher doping concentration in the portions of anode region 12 displaced away from substrate surface 14. As will subsequently be described, the retrograde doping profile is advantageous for forming a metal-semiconductor junction in anode region 12. In one embodiment, anode region 12 is formed by the ion implantation of phosphorous using an implantation energy of about 500 keV to about 700 keV and, preferably, an implantation energy of about 600 keV. Anode region 12 is preferably formed to have a relatively low doping concentration. In one embodiment of the invention, a phosphorus ion implantation dose of about 1.0×10¹³ to about 2.0×10¹³ ions/cm² and, preferably, about 1.5×10¹³ ions/cm² is used to form anode region 12. Once the doping process is complete, subsequent annealing processes will diffuse the phosphorus dopant and form the retrograde doping profile.

First and second cathode regions 16 and 18 reside in anode region 12 and are formed adjacent to first and second isolation regions 20 and 22, respectively. In the illustrated embodiment, first and second cathode regions 16 and 18 are heavily-doped, n-type regions. In one embodiment of the invention, cathode regions 16 and 18 are formed, for example, by ion implantation of phosphorous using an implantation dose of about 3×10¹⁵ to about 5×10¹⁵ ions/cm².

Metal layers 24 and 28 contact first and second cathode regions 16 and 18, respectively, at substrate surface 14. A metal layer 30 contacts anode region 12 at substrate surface 14 in a location intermediate to metal layers 24 and 28. Metal-semiconductor junctions are formed at the interface between the metal layers and the underlying substrate regions.

In the metal junction diode illustrated in FIG. 1, a metal semiconductor junction 32 formed between metal layer 30 and anode region 12 will have a large depletion region (not shown) extending into anode region 12. The depletion region is enhanced by the relatively low doping concentration in anode region 12. Additionally, the retrograde doping profile within anode region 12 further removes the peak dopant concentration away from substrate surface 14, which creates a highly resistive substrate region near surface 14. The lightly-doped and highly-resistive substrate region enhances the depletion region and reduces electron tunneling, thereby improving diode performance.

Conversely, because of the relatively high doping concentration in cathode regions 16 and 18, the metal-semiconductor junctions in cathode regions 16 and 18 will have very small depletion regions. In particular, the metal-semiconductor contacts in cathode region 16 and 18 will be essentially ohmic contacts and the associated depletion regions will not create a barrier to electron tunneling. Conversely, as described above, the depletion region at metal-semiconductor junction 32 and anode region 12 is sufficient to effectively prevent electron tunneling. Accordingly, a diode is created within anode region 12 that will permit electrical current to flow in only one direction. Those skilled in the art will recognize that the metal junction diode illustrated in FIG. 1 can be fabricated using conventional CMOS fabrication techniques.

To provide a metal junction diode compatible with CMOS process technology, metal layers 24, 28 and 30 are preferably metal silicide layers fabricated using a conventional silicidation process. For example, in one embodiment of the invention, metal layers 24, 28 and 30 are formed by reacting a metal silicide with silicon at substrate surface 14.

Those skilled in the art will appreciate that many metal silicide fabrication methods are possible. In one process embodiment of the invention, a selective silicidation process is carried out. A metal silicide is formed by first cleaning substrate surface 14 to remove any residual oxide or other oxide materials from substrate surface 14. Then, a sputtering process is carried out to remove about 40 angstroms to about 50 angstroms of silicon from the substrate surface 14. Next, a layer of oxygen-reactive metal is deposited to react with any residual oxygen on substrate surface 14. In a preferred embodiment, titanium is deposited to a thickness of about 80 angstroms. Once the oxygen-reactive metal is deposited, a silicide-forming metal is deposited onto the substrate. In a preferred embodiment, the silicide-forming metal is cobalt, which is deposited to a thickness of about 125 angstroms.

A metal blocking mask (not shown), which can be a patterned dielectric layer, is then formed on substrate surface 14 to protect regions 34 and 36. A layer of silicide-forming metal, such as a refractory metal, is then formed in contact with anode region 12 at locations not protected by the metal blocking mask (not shown).

Once the silicide-forming metal is deposited, a thermal treatment process is carried out to initiate a chemical reaction between silicon at substrate surface 14 and the deposited metal layer. In one embodiment, a rapid thermal annealing process is carried out at a temperature of about 470° C. for a time period of about 30 seconds to about 100 seconds. Following this thermal treatment, unreacted portions of the deposited metal layer are then removed by selectively etching away unreacted metal. Once the unreacted metal is removed, a second annealing process, if desired, can be carried out to ensure that the remaining metal is substantially completely reacted with silicon. For example, a second rapid thermal annealing process can be carried out a temperature higher than the first annealing process and for a time period of about 30 seconds to about 100 seconds. In one embodiment, the second annealing process is carried out at a temperature of about 825° C. The second annealing process reduces the electrical resistance of the silicide layer and stabilizes the silicide material.

After annealing the substrate, a chemical etching process is carried out to remove unreacted metal from substrate surface 14. In one embodiment, a wet chemical etching process is used to remove unreacted silicide-forming metal.

To enhance the performance of the metal junction diode illustrated in FIG. 1, additional dope regions, or series resistance abatement regions, can be formed to reduce the series resistance within the diode. For example, FIG. 2 illustrates, in cross-section, the metal junction diode illustrated in FIG. 1 having a buried region 38 and anode region 12 extending between cathode regions 16 and 18. Buried region 38 can be formed by implantation of n-type doping prior to forming metal layers 24, 28 and 30. Preferably, buried region 38 is formed at a depth in anode region 12 such that it is below the depletion region created by metal-semiconductor junction 32.

A further reduction in series resistance can be obtained by forming extension regions 40 and 42 in anode region 12 that extend from cathode regions 16 and 18 toward metal layer 30. Extension regions 40 and 42 can be formed by implantation of an n-type dopant either before or after forming cathode regions 16 and 18.

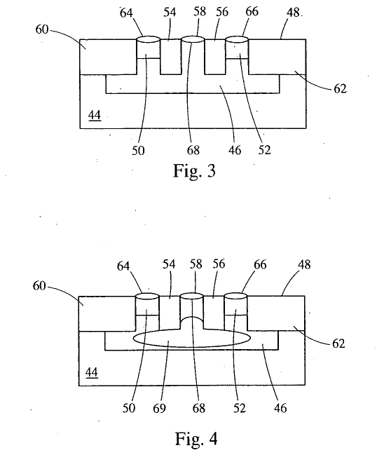

A metal junction diode configured in accordance with another embodiment of the invention is illustrated in FIG. 3. A semiconductor substrate 44 has an anode region 46 that extends from a substrate surface 48 into semiconductor substrate 44. Cathode regions 50 and 52 reside in anode region 46 and extend from substrate surface 48 into anode region 46. Isolation regions 54 and 56 separate cathode regions 50 and 52 from a metal layer 58 residing at substrate surface 48. Further, isolation regions 60 and 62 reside in semiconductor substrate 44 adjacent to anode regions 50 and 52, respectively. Metal layers 64 and 66 contact cathode regions 50 and 52, respectively, at substrate surface 48. Accordingly, metal layer 64 is bounded by isolation regions 54 and 60, and metal layer 66 is bounded by isolation regions 48 and 56. In turn, metal layer 58 is bounded at substrate surface 48 by isolation regions 54 and 56. In one embodiment of the invention, isolation regions 48, 54, 56 and 60 are trench isolation regions formed by shallow-trench-isolation (STI) fabrication methods.

The metal junction diode illustrated in FIG. 3 includes a metal-semiconductor junction 68 in anode region 46. In similarity with the embodiment described above, a relatively thick depletion region (not shown) is formed in anode region 46 at metal-semiconductor junction 68. Further, cathode regions 50 and 52 are fabricated to have a relatively high doping concentration, such that substantially ohmic contacts are formed at the metal-semiconductor junctions and cathode regions 50 and 52.

In the fabrication of the metal junction diode illustrated in FIG. 3, in contrast to the previous embodiment, metal layers 58, 64, and 66 can be fabricated without forming a metal blocking mask on substrate surface 48. A metal blocking mask is unnecessary in view of the formation of isolation regions prior to forming metal layers 58, 64, and 66. In particular, metal layers 58, 64, and 66 are preferably fabricated by depositing a silicide-forming metal layer on substrate surface 48, followed by thermal annealing to react the metal layer with silicon exposed at substrate surface 48 between the isolation regions.

In similarity with the previous embodiment, the metal contact layers in the metal-junction diode illustrate in FIG. 3 can be formed by a selective silicidation process. A refractory metal is deposited onto substrate surface 48 followed by thermal annealing to selectively form a refractory metal silicide in cathode regions 50 and 52, and in anode region 46.

In accordance with further embodiment of the invention, a buried layer 68 can be formed in anode region 46 to enhance the diode performance, as illustrated in FIG. 4. A buried layer 69 is preferably formed by implanting an n-type doping, such as phosphorous, into anode region 46 prior to forming cathode regions 50 and 52. As in the previous embodiment, buried region 58 should be formed in a depth so as not to interfere with the depletion region formed at metal-semiconductor interface 68. In accordance with one embodiment of the invention, phosphorous is implanted at an implant energy of about 200 keV to about 300 keV using an implant dose of about 1.8×10¹²to about 1.20×10¹³ ions/cm². As illustrated in FIG. 4, buried layer 69 can be extended toward metal-semiconductor interface 68 additional implantation of anode region 46

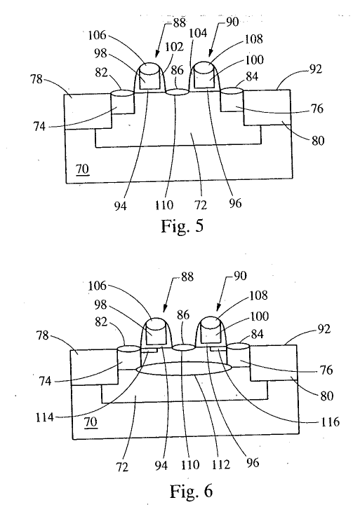

A metal-junction diode configured in accordance with yet another embodiment of the invention is illustrated in FIG. 5. A semiconductor substrate 70 includes an anode region 72 having first and second cathode regions 74 and 76 formed therein. First and second cathode regions 74 and 76 reside adjacent to isolation regions 78 and 80, respectively. Metal layers 82 and 84 contact cathode regions 74 and 76, respectively. A metal layer 86 is spaced apart from metal layers 82 and 84 by first and second gate structures 88 and 90.

Gate structures 88 and 90 reside on a substrate surface 92 and overlie anode region 72 in locations intermediate to metal layers 82, 84, and 86. Gate structures 88 and 90 include gate dielectric layers 94 and 96 that separate gate layers 98 and 100 from substrate surface 92, respectively. Gate structures 88 and 90 also include sidewall spacers 102 and 104 adjacent to the sidewalls of gate layers 98 and 100, respectively. A metal region 106 resides at an upper portion of gate layer 98, and a metal region 108 resides at an upper portion of gate layer 100.

In accordance with the illustrated embodiment, gate structures 88 and 90 can be fabricated using conventional CMOS gate electrode fabrication techniques. Accordingly, gate dielectric layers 94 and 96 can be formed using a standard gate dielectric layer fabrication process. Also, gate layers 98 and 100 can be fabricated by conventional gate fabrication techniques. For example, gate layers 98 and 100 can be polycrystalline silicon, or other transistor gate material such as refractory metal, polycide, and the like. Gate layers 98 and 100 are fabricated using conventional lithographic and etching techniques. Also, sidewall spacers 102 and 104 can be formed by conventional side wall spacer forming processes, such as the deposition and isotropic etching of a dielectric material, such as silicon oxide.

In similarity with the embodiments described above, metal layers 82, 84, and 86 are preferably metal silicide layers formed by the deposition of the refractory metal followed by thermal annealing. In accordance with one embodiment of the invention, a refractory metal is deposited to overlie substrate surface 92 and gate layers 98 and 100. In addition to the metal diode contact layers, a refractory metal silicide is also formed at the exposed upper surfaces of gate layers 98 and 100. Accordingly, metal layers 82, 84, 86, and metal regions 106 and 108 are refractory metal layers formed by a conventional silicidation process. Because gate structures 88 and 90 are fabricated prior to forming the metal contact layers, a metal blocking mask is unnecessary to protect surface regions of anode region 72 from contact by a refractory metal layer. Further, sidewall spacers 102 and 104 substantially prevent metal regions 106 and 108 from contacting metal layers 82, 84, or 86.

As in the embodiments described above, a metal-semiconductor junction 110 is formed where metal layer 86 contacts anode region 72. A deep depletion region is created by the combination of the metal contact and the relatively low doping concentration of anode region 72. Conversely, substantially ohmic contacts are formed in cathode regions 74 and 76, where the doping concentration is substantially higher.

Those skilled in the art will recognize the structure illustrated in FIG. 5 as generally illustrating a poly-bounded diode structure. Accordingly, a metal junction diode fabricated in accordance with the embodiment illustrated in FIG. 5 offers improved performance through relatively low leakage current. Further, the gate-channel regions created in anode region 72 by gate structures 88 and 90 reduce the overall series resistance of the metal junction diode.

A further reduction in series resistance can be obtained by configuring the metal junction diode illustrated in FIG. 5 with a buried region 112, as illustrated in FIG. 6. In similarity with the embodiments of the invention described above, buried region 112 is formed at a depth and anode region 72 so as not to contact the depletion region formed at metal-semiconductor junction 110. Also, doped extension regions 114 and 116 can be formed at substrate surface 92 extending from cathode regions 74 and 76, respectively. Extension regions 114 and 116 effectively alter the conductivity of the channel regions formed in anode region 72 below gate structures 88 and 90.

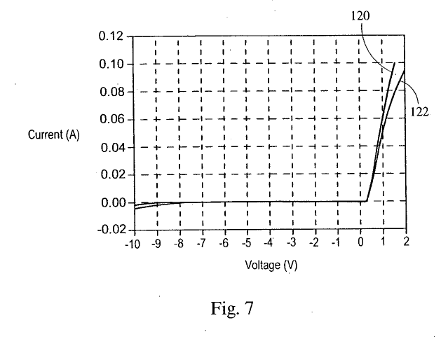

Metal junction diodes fabricated in accordance with the various embodiments of the invention generally display typical Schottky diode characteristics. FIG. 7 is a plot of current versus voltage for two metal junction diodes fabricated in accordance with the invention. The diodes were fabricated with metal contacts formed by depositing a layer of titanium having a thickness of about 80 angstroms followed by depositing a cobalt having a thickness of about 125 angstroms. Once the metal layers were formed, a rapid thermal annealing process was carried out at about 470° C. for about 30 seconds. After which, a cleaning process was carried out to remove unreacted cobalt from the substrate surface. Then, a second annealing process was carried out at about 825° C. for about 30 seconds. In the case of cobalt silicide metal contacts, the metal-semiconductor junction produces a depletion width of about 50 nanometers to about 100 nanometers in the anode region.

The plot of FIG. 7 illustrates the current-voltage characteristics for a first diode 120 having a diode area of about 83.16 square microns, and a second diode 122 having a diode area of about 55.44 square microns. As illustrated in FIG. 7, both diodes exhibit a return on voltage of about 0.3 volts. Accordingly, the diodes fabricated in accordance with the various embodiments of the invention using conventional CMOS fabrication techniques exhibit typical current-voltage diode characteristics.

Thus, it is apparent that it has been described in accordance with the invention, a metal junction diode and fabrication process that fully provides the advantages set forth above. Although the invention has been described and illustrated with reference to specific illustrative embodiments thereof, it is not intended that the invention be limited to those illustrative embodiments. Those skilled in the art will recognize that variations and modifications can be made without departing from the spirit of the invention. For example, a wide variety of materials and processes can be used to fabricate the metal junction diodes described above. It is therefore intended to include within the invention also its variations and modifications that fall within the scope of the appended claims and equivalents thereof.

1. A metal junction diode comprising:
a substrate having a substrate surface and having a lightly-doped region extending into the substrate from the substrate surface;
first and second cathode regions in the lightly-doped region extending into the substrate from the substrate surface and separated by an anode region; and
metal silicide layers contacting the first and second cathode regions and the anode region at the substrate surface.

2. The metal junction diode of claim 1 further comprising extension regions at the substrate surface extending from the first and second cathode regions into the anode region and spaced apart from the metal silicide layer contacting the anode region.

3. The metal junction diode of claim 2 further comprising gate electrodes overlying the substrate surface on either side of the metal silicide layer contacting the anode region and separated from the substrate surface by a dielectric layer.

4. The metal junction diode of claim 1 further comprising gate electrodes overlying the substrate surface on either side of the metal silicide layer contacting the anode region and separated from the substrate surface by a dielectric layer.

5. The metal junction diode of claim 1 further comprising electrical isolation regions at the substrate surface and extending into the substrate between the metal silicide layers contacting the first and second cathode regions and the metal silicide contacting layer anode region.

6. The metal junction diode of claim 1 wherein the anode region comprises a retrograde well region in which a doping concentration in the well region decreases in a direction from a interior portion of the well region toward the substrate surface.

7. The metal junction diode of claim 1 further comprising a depletion region in the anode region adjacent to the metal silicide layer contacting anode region.

8. The metal junction diode of claim 7 further comprising a series resistance abatement region in the substrate below the depletion region.

9. The metal junction diode of claim 1, wherein the first and second cathode regions and the anode region comprise region having n-type conductivity, and wherein the metal silicide layers comprise cobalt silicide.

10. A metal junction diode comprising:
a substrate having first and second cathode regions separated by an anode region; and
cobalt silicide layers contacting the first and second cathode regions and the anode region,
wherein the anode region has a doping concentration sufficient to create a depletion region in the anode region adjacent to the metal silicide layer contacting anode region.

11. The metal junction diode of claim 10, wherein the anode region comprises a retrograde well region in which the doping concentration decreases in a direction from a interior portion of the well region toward the substrate surface.

12. The metal junction diode of claim 11, wherein the first and second cathode regions comprise n-type doped regions having a first doping concentration, wherein the anode region comprises an n-type doped region having a second doping concentration, and wherein the first doping concentration is greater than the second doping concentration.

13. The metal junction diode of claim 10, wherein the substrate includes a substrate surface, and wherein a structure at the substrate surface defines the anode region.

14. The metal junction diode of claim 13, wherein the structure comprises gate electrodes overlying the substrate surface on either side of the cobalt silicide layer contacting the anode region and a gate dielectric layer separating gate electrodes from the substrate surface.

15. The metal junction diode of claim 13, wherein the structure comprises electrical isolation regions at the substrate surface between the cobalt silicide layers contacting the first and second cathode regions and the cobalt silicide layer contacting layer anode region and extending into the anode region.

16. A process for fabricating metal junction diode comprising:
providing a silicon substrate of a first conductivity type and having a substrate surface;
forming an anode region in a semiconductor substrate having a second conductivity type, wherein a dopant concentration in the anode region increases in a direction away from the substrate surface;
forming cathode regions in the semiconductor substrate having the second conductivity type; and
forming metal silicide contacts to the anode region and to the cathode regions.

17. The process of claim 16, wherein forming an anode region comprises ion implantation of an n-type dopant.

18. The process of claim 16, wherein forming metal silicide contacts comprises depositing a refractory metal layer onto the substrate surface at the anode region and the cathode regions, and annealing the silicon substrate to form a metal silicide layer.

19. The process of claim 16, wherein depositing a refractory metal layer comprises depositing a cobalt layer.

20. The process of claim 16 further comprising forming a series resistance abatement region in the substrate in the anode region, wherein the abatement region is spaced away from the metal silicide contact by a depletion region.
